(19) United States
(12) Patent Application Publication
(10) Pub. No.: US 2025/0113599 A1
(43) Pub. Date: Apr. 3, 2025

(54) METHODS FOR DOPING 2D TRANSISTOR DEVICES AND RESULTING ARCHITECTURES

(71) Applicant: Intel Corporation, Santa Clara, CA (US)

(72) Inventors: Rachel A. Steinhardt, Beaverton, OR (US); Kevin P. O'Brien, Portland, OR (US); Ashish Verma Penumatcha, Hillsboro, OR (US); Carl Hugo Naylor, Portland, OR (US); Kirby Maxey, Hillsboro, OR (US); Pratyush P. Buragohain, Hillsboro, OR (US); Chelsey Dorow, Portland, OR (US); Mahmut Sami Kavrik, Eugene, OR (US); Wouter Mortelmans, Portland, OR (US); Marko Radosavljevic, Portland, OR (US); Uygar E. Avci, Portland, OR (US); Matthew V. Metz, Portland, OR (US)

(73) Assignee: Intel Corporation, Santa Clara, CA (US)

(21) Appl. No.: 18/477,414

(22) Filed: Sep. 28, 2023

(51) Int. Cl. H01L 27/092; H01L 29/06; H01L 29/26; H01L 29/66; H01L 29/775

(52) U.S. Cl. CPC H10D 84/85; H10D 30/43; H10D 62/121; H10D 62/80; H10D 99/00

(57) ABSTRACT

Methods for doping 2D transistor devices and resulting architectures. The use and placement of oxide dopants, such as, but not limited to, GeOx, enable control over threshold voltage performance and contact resistance of 2D transistor devices. Architectures include distinct stoichiometry compositions.

### BACKGROUND

Two-dimensional (2D) materials show great promise for small scale transistors because they are able to retain semiconductor properties at monolayer thicknesses. To enhance the performance of transistors that implement 2D materials (2D transistor devices), methods of doping are needed for various applications.

### BRIEF DESCRIPTION OF THE DRAWINGS

FIGS. 1A and 1B are simplified cross-sectional views of a back-gated single transistor, in accordance with various embodiments.

FIG. 2 is a perspective view of a stacked nanoribbon transistor, in accordance with various embodiments.

FIG. 3A is a simplified top down or plan view of a stacked nanoribbon transistor.

FIG. 3B is a simplified cross-sectional diagram of a stacked nanoribbon transistor in accordance with various embodiments described herein.

FIG. 4A is a simplified cross-sectional diagram showing another exemplary back-gated single transistor, in accordance with various embodiments.

FIG. 4B a simplified cross-sectional diagram of another stacked nanoribbon transistor in accordance with various embodiments described herein.

FIG. 5A is a simplified cross-sectional diagram showing another exemplary back-gated single transistor, in accordance with various embodiments.

FIG. 5B is a simplified cross-sectional diagram of another stacked nanoribbon transistor in accordance with various embodiments described herein.

FIG. 6 is an exemplary method for manufacturing various embodiments described herein.

FIG. 7 is a graph illustrating a shift in gate threshold voltage achieved with various embodiments described herein.

FIG. 8 is a top view of a wafer and dies that may be included in a microelectronic assembly, in accordance with any of the embodiments disclosed herein.

FIG. 9 is a simplified cross-sectional side view showing an implementation of an integrated circuit on a die that may be included in various embodiments, in accordance with any of the embodiments disclosed herein.

FIG. 10A to FIG. 10D are simplified perspective views of example planar, FinFET, gate-all-around, and stacked gate-all-around transistors, as may be implemented in various embodiments.

FIG. 11 is a cross-sectional side view of a microelectronic assembly that may include any of the embodiments disclosed herein.

FIG. 12 is a block diagram of an example electrical device that may include any of the embodiments disclosed herein.

### DETAILED DESCRIPTION

The two-dimensional (2D) materials show great promise for small scale transistors for a variety of reasons. First, 2D materials, because of their monolayer channel thickness, enable better gate control (a power improvement). Also, at these thicknesses, 2D materials exhibit better mobility than silicon (a performance improvement). Additionally, due to the high effective mass and larger band gap of 2D materials, they exhibit lower source-drain tunneling. (a power improvement).

As used herein, 2D materials can be transition metal dichalcogenides (TMD), canonical examples include but are not limited to, MoS2, WS2, and WSe2. The 2D materials can have a thickness in a range of 0.7 nanometers (nm) to 2.8 nm+/−10%. Due to the reduced, often sub-nanometer, thickness of the 2D material, doping the 2D material is inherently challenging. Therefore, it is desirable to develop methods of doping the 2D materials to enhance the performance of the transistors that employ 2D materials (2D transistors devices), and to tailor the 2D doping to meet application- or device-specific performance goals.

Among available ways to enhance 2D transistor performance are to control threshold voltages (VT) and contact resistance. Having the ability to control or shift a transistor's threshold voltage (VT) enables the ability to control the range of operating voltages for the transistor or decrease the operating voltage of the transistor. Having the ability to control the contact resistance of a transistor determines the maximum drive current and clock frequency achievable in devices utilizing these transistors. As used herein, “contact resistance” is a resistance measured at the interface between a source material and a source contact metal and/or between a drain material and a drain contact metal. Often, it is desirable to control the threshold voltage (VT) and/or contact resistance in transistors to achieve transistor/device performance goals. However, suitably tailoring these metrics while not adversely affecting other performance targets is technically challenging.

Some solutions have been explored using a tungsten oxide (WOₓ) to dope tungsten diselenide (WSe₂). However, doping 2D transistors to control performance remains technically challenging.

Embodiments disclosed herein propose a technical solution to the above-described technical problems in the form of methods for doping 2D transistor devices and resulting architectures. Doping the 2D material can un-pin the Fermi level and can realign or decrease the Schottky-barrier width of a transistor. The herein described methods include 1) using oxides to dope a 2D channel region to cause a gate threshold voltage shift, which advantageously enables control over the operating voltage (and range thereof) of the transistor; 2) using oxides to dope a region under a spacer to reduce the associated contact resistance (based on the decrease in the Schottky-barrier width); and 3) using GeOx in at least some of these tasks. These concepts are developed in more detail below.

Aspects of the present disclosure, such as the presence of Germanium oxide (GeOx) in a 2D transistor device, may be discoverable using cross-sectional transmission electron microscopy (TEM) images and corresponding compositional analysis, such as Time of Flight Secondary Ion Mass Spectrometry (ToF SIMS), Energy Dispersive X-ray spectroscopy (EDX), or Electron Energy Loss Spectroscopy (EELS) to reveal the stoichiometry and electronic structure. Additionally, the gate threshold voltage and contact resistance of architectures and devices can be tested in a laboratory and can reveal that aspects of the present disclosure have been practiced, as described in more detail below.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

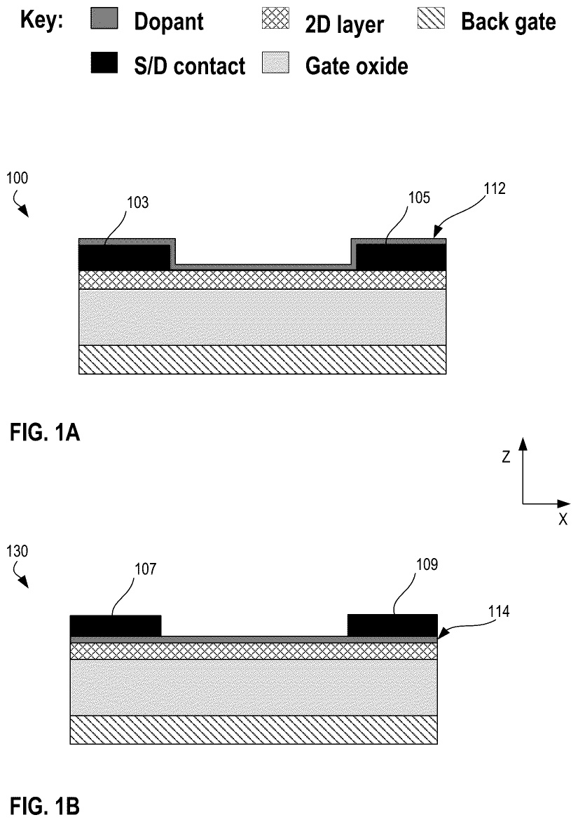

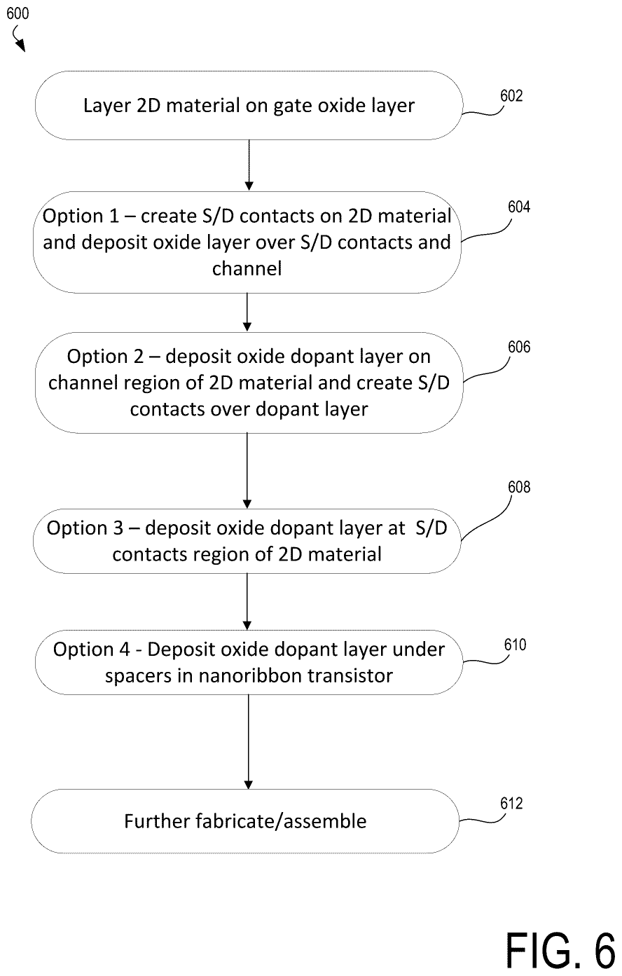

FIGS. 1A to 5B are simplified diagrams showing views of various 2D transistor devices doped with oxides, as described herein below. FIG. 6 is a flowchart for an exemplary method for fabricating embodiments described herein. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, cause the machine to perform some or all of the steps of the method 600. In addition to techniques specifically referenced herein, the method 600 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, thermal treatments, etc.

Embodiment 100 and embodiment 130 show embodiments of a planar 2D transistor device or field effect transistor device with a back-gate metal layer at the bottom, followed by (moving upward in the figure, or in the +Z direction) a layer comprising oxide (also referred to as an “oxide layer” or “gate oxide layer”), which is overlaid with a 2D metal layer. Various embodiments may further include, below the back-gate metal layer, a substrate layer (not shown). The substrate layer can be silicon, silicon oxide, gallium nitride, or another suitable material.

The back-gate metal layer (diagonal lines) generally provides back-gating for the transistor device, and can comprise a metal (e.g., platinum, palladium, tungsten, molybdenum, tantalum, copper, aluminum, nickel, cobalt, iron, gold, silver, or combinations thereof). The back-gate metal layer can be in a range from 5 nm+/−10% to 500 nm+/−10% thick.

The oxide layer between the back-gate metal layer and the 2D layer (light gray in the figures) can comprise a suitable oxide, such as aluminum oxide (Al₂O₃), hafnium oxide (HfO₂), zirconium oxide (ZrO₂), aluminum-doped hafnium oxide, silicon-doped hafnium oxide, niobium-doped hafnium oxide, titanium-doped hafnium oxide, germanium-doped hafnium oxide, gallium-doped hafnium oxide, titanium dioxide, tantalum pentoxide, niobium pentoxide, silicon dioxide (SiO₂), carbon-doped silicon dioxide, fluorine-doped silicon dioxide, hydrogen-doped silicon dioxide, or combinations thereof. In various embodiments, the oxide layer can have a thickness from 1 nm+/−10% to 5 nm+/−10%.

At 602, channel material (the layer comprising 2D material) is overlaid on gate oxide material. The 2D material (hatched) is grown or transferred on an upper surface of the oxide layer, as shown. The 2D material may be in a range of 0.7 nm to 2.8 nm thick (this thickness is a function of the number of atoms per layer, with 0.7 nm representing one 2D layer). The 2D material is to be channel material as well as part of source and drain regions of a transistor architecture. In various embodiments, the 2D material may be a chalcogenide, and may further be a semiconducting dichalcogenide or a transition metal dichalcogenide (TMD). A TMD may be a semiconductor of type MC2, with M being a transition metal (e.g., Mo or W) and C being a chalcogen atom(s) (e.g., S, Se, or Te). The 2D material may comprise tungsten diselenide (WSe₂), Molybdenum diselenide (MoSe₂), Molybdenum ditelluride (MoTe₂), tungsten disulfide (WS₂), or the like. In other embodiments, the 2D material may comprise Indium diselenide (In Se₂) or In₂Se₃.

In various embodiments, growing the 2D material (at 602) may be performed at the large wafer scale and/or be grown by chemical vapor deposition (CVD) or metal organic chemical vapor deposition (MOCVD) techniques. In various embodiments, the channel material will be referred to as a 2D material, but in practice it may be a monolayer (e.g., only one layer of the constituent atoms of the material) or a multi-layer (e.g., including up to a few layers of the constituent atoms of the material).

In some embodiments, the 2D layer, or layer comprising 2D material is patterned with lithography. In other embodiments, the oxide layer is patterned with lithography and the 2D material is grown only on the patterned areas of the oxide layer. Embodiments are understood to include a plurality of dedicated S/D regions, even though many of the images in the figures are simplified to just show one.

The oxide to be implemented for 2D doping in embodiments is depicted in the illustrations as a dark gray “dopant layer.” The dopant layer comprises a dopant material, the dopant material comprises an oxide, such as, a tungsten, molybdenum, magnesium, aluminum, germanium, vanadium, or indium oxide (WOx, MoOx, MgOx, Al2Ox, GeOx, VOx, or In2Ox, where x may be from 1-4). As used herein, “doping” means remote charge doping. Wherein conventional silicon doping means adding a different atom to the silicon crystal (also called substitutional doping), remote charge doping involves putting an oxide layer next to the TMD and the oxide layer can either pull an electron from the 2D material (TMD) (thus p doping or hole doping) or the oxide layer can push an electron in the channel (thus n doping or electron doping). The doping amount achieved by the dopant layer is a function of the coverage of the oxide layer on the TMD, the number of dangling bonds in the oxide layer, and the band offsets between the oxide layer and the TMD. This methodology is similar to the use of 2D electron gases in III-V materials.

Processing/architectural options 1 (at 604) and 2 (at 606) are illustrated with embodiments 100 and 130. In these options, the dopant layer 112/114 (dark gray) is overlaid on at least the channel region of the 2D layer (the channel region being between the first S/D region (103/107) and the second S/D region (105/109), as shown).

The dopant layer 112/114 is contiguous from left to right in the figures. In embodiment 100 the dopant layer 112 is further overlaid on/above the first S/D contact 103 and on/above the second S/D contact 105, consequently having a profile that is not linear, as shown (also, not planar in a 3D view). In embodiment 130 the dopant layer 114 is overlaid on the 2D layer such that it is below the first S/D contact 107 and the second S/D contact 109, consequently having a profile that is substantially linear in the 2d image, as shown (and would be planar in a 3D image). The S/D contacts may comprise a metal, such as (e.g., antimony, bismuth, platinum, copper, aluminum, nickel, cobalt, iron, tin, gold, indium, tungsten, ruthenium, or combinations thereof).

At 604, processing option 1, S/D contacts are placed over 2D material, and an oxide “dopant layer” is overlaid on a channel region and S/D contacts of respective transistors (FIG. 1A).

At 606, processing option 2, the oxide dopant layer is overlaid on the 2D material and respective S/D contacts are created over the dopant layer (FIG. 1B).

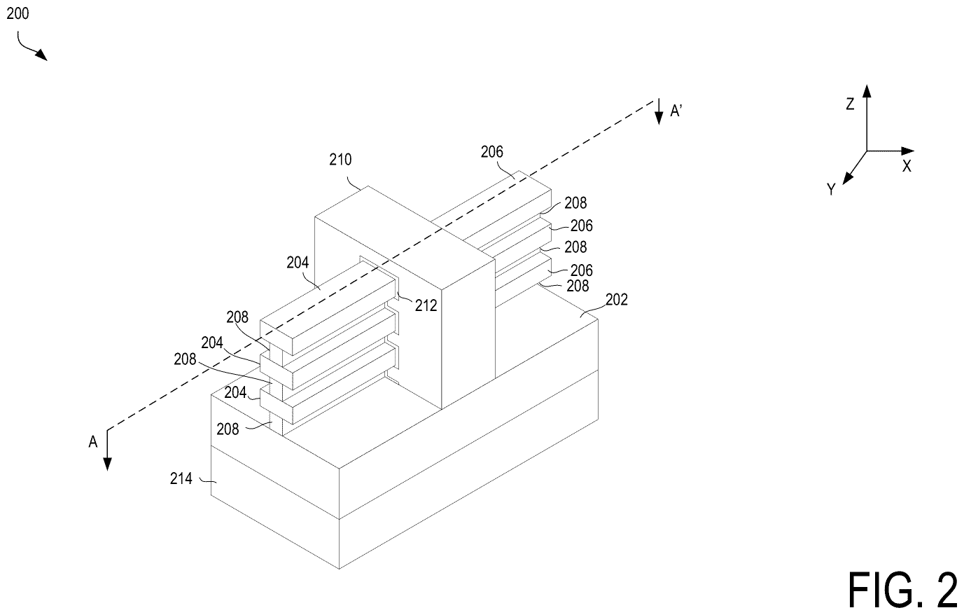

The above two approaches each result in the dopant layer 112/114 being on top of the channel region; these approaches can further be applied to a stacked nanoribbon transistor. Referring now to FIG. 2, a perspective view of a stacked nanoribbon transistor 200 is shown for reference. The stacked nanoribbon transistor 200 may also be referred to as a gate-all-around transistor, a nanowire transistor, a nanosheet transistor, etc. The stacked nanoribbon transistor 200 has one or more source fins 204 (with a source contact) and one or more drain fins 206 (with a drain contact). Spacers 208 may be interleaved between the source fins 204 and interleaved between the drain fins 206. In various embodiments, an additional layer 212 may surround a channel region of the fins 204, 206. In some scenarios, the layer 212 can comprise a ferroelectric material, and in other scenarios, the layer 212 can be a dielectric or insulating material. A gate 210 surrounds the layer 212 and/or the channel regions between respective source fins 204 and drain fins 206.

In the illustrative embodiment, the substrate 214 supports the buffer layer 202 and the rest of the transistor. As described in connection with FIG. 1, the substrate 214 may be silicon, silicon oxide, gallium nitride, etc. The buffer layer 202 may be any suitable material on which the spacers 208 and/or the fins (source fins 204 and drain fins 206) may be grown.

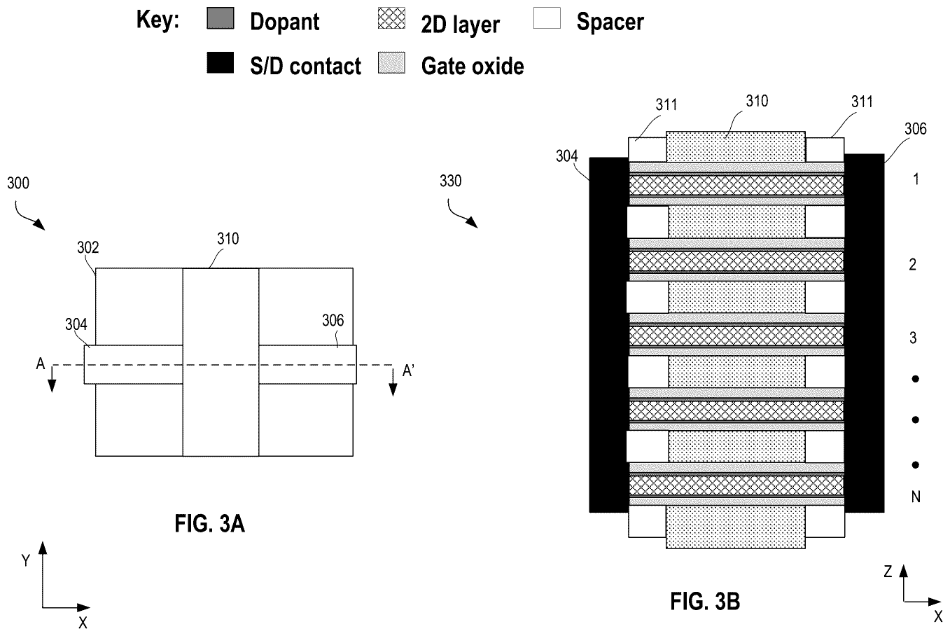

The transistor embodiment 200 may include a plurality (N) of transistors, represented by a respective plurality (N) of source fins 204 and drain fins 206. In various embodiments, N can be 1-10. In other embodiments, N can be greater than 10. Turning to FIG. 3A and FIG. 3B, and with continued reference to FIGS. 1-2, nanoribbon top-down view 300 shows cross-section A-A′ through a source fin 304, gate 310, and drain region 306, and an exemplary resulting cross-sectional image 330.

The cross-sectional image 330 illustrates, for a plurality of 2D transistors, a respective plurality (N) of channel regions, located between individual source fins 304 and drain fins 306. The channel regions in FIG. 3B look like rungs on a ladder and illustrate a dopant layer in between the gate oxide layer and the 2D channel. The illustrative gate 310 may comprise materials, such as platinum, antimony, bismuth, iridium, copper, aluminum, or other metal, oxides with high electric conductivity, including RuO2, IrO2, and ITO, polysilicon, etc. The gate 310 may comprise gate oxide and gate metal and may be in a range of 5 nm+/−2 nm. The “gate all around” aspect of this architecture enables the dopant layer to appear in the two-dimensional image to be on top of the 2D metal layer and underneath the 2D metal layer, as illustrated.

The source 304 contact and drain 306 contact may comprise a combination of materials, such as a first material that integrates well with the 2D material in the fins or rungs of the N different channel regions, and a second material that is a stiffer and highly conductive material or metal. In various embodiments, the contact width (left to right in FIG. 3B) may be 7 nanometers (nm)+/−10%. Spacers (white blocks in embodiment 330) may be used to create 5 nm+/−30% distance between the S/D materials and the gate 310 material. The spacers may comprise silicon nitride (SiN), silicon dioxide (SiO₂), and/or amorphous Boron Nitride (BN).

The fins or ribbons or rungs are understood to be substantially coplanar, or substantially parallel in two dimensions, from left to right in the figure. When stacking a second embodiment 330 to the right or left of the depicted embodiment 330, various architectures will separate the S/D contacts with an insulator (not shown) of about 5-10 nm thick+/−10%.

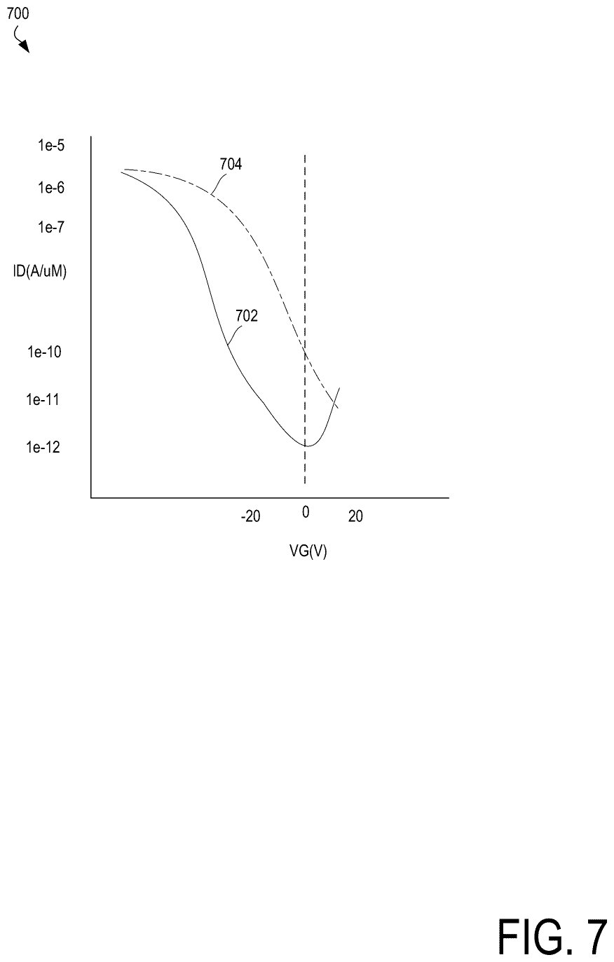

A compositional analysis of a planar 2D transistor and/or of a stacked nanoribbon transistor that practices the architectures/methods disclosed herein would reveal the 2D material and the dopant layer of oxide material arranged as described herein. With reference to FIG. 7, using the dopant layer 112/114 of oxide material on the channel region as described can shift the gate threshold voltage. In the graph 700, drain current is mapped on the Y axis and gate voltage is mapped on the X axis. A reference 2D transistor performance is shown with line 702, which exhibits a threshold inflection at less than-20 volts and a “treated” 2D transistor (using the dopant layer of oxide material as described herein) is shown with line 704, which exhibits a threshold inflection around 0 volts. The inflection shifts to a higher gate voltage than that of the reference transistor, as illustrated. As mentioned, having control over the gate threshold voltage advantageously enables control over the operating voltage (and range thereof) of the transistor.

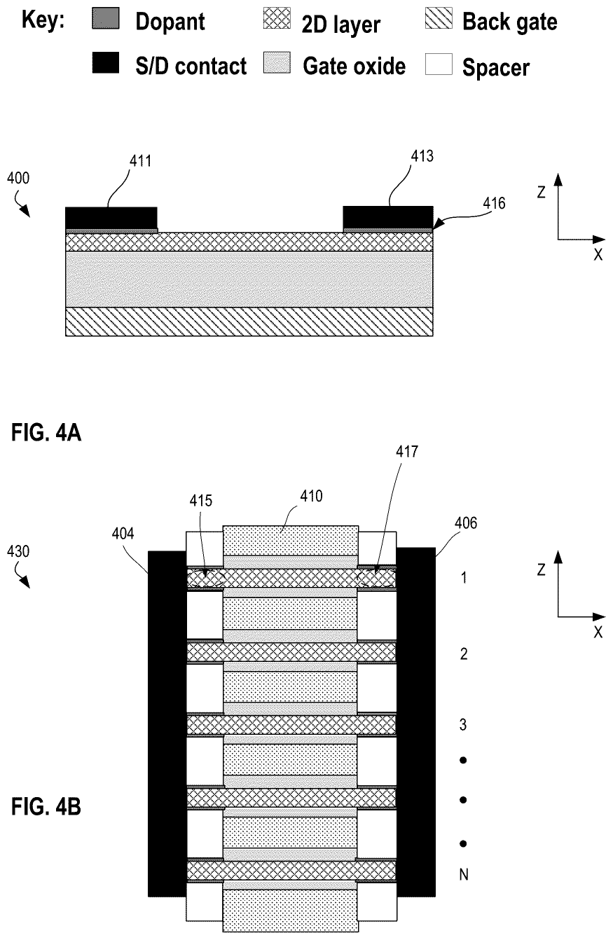

FIG. 4A and FIG. 4B illustrate embodiments that place the dopant layer of oxide near the S/D contacts rather than over the channel region (processing option 3—at 608). Embodiment 400 of a planar 2D transistor shows first S/D contact 411 and second S/D contact 413, separated laterally (left to right in the figure) by the channel region. Only the contact regions are doped. The dopant layer 416 is shown between the first S/D contact 411 and the 2D layer, and also between the second S/D contact 413 and the 2D layer; the dopant layer 416 is not located over the channel region. Said differently, in this embodiment, the S/D contact regions of the 2D metal are doped, but not the channel region.

Carrying this concept forward into an exemplary stacked nanoribbon embodiment 430, the dopant layer can be located between the spacers and the 2D metal, such that they create regions 415/417 in the 2D metal that are doped: the doped region 415 is associated with a source contact (or first S/D contact) and the doped region 417 is associated with a drain contact (or a second S/D contact). The contact resistance of the first S/D contact 432 and the second S/D contact 434 can be measured. In various embodiments, the contact resistance under the S/D contact 432 and the second S/D contact 434 will be less than 10 ohm/micrometer. In other embodiments, the contact resistance under the S/D contacts 432/434 will be less than 100 ohm/micrometer.

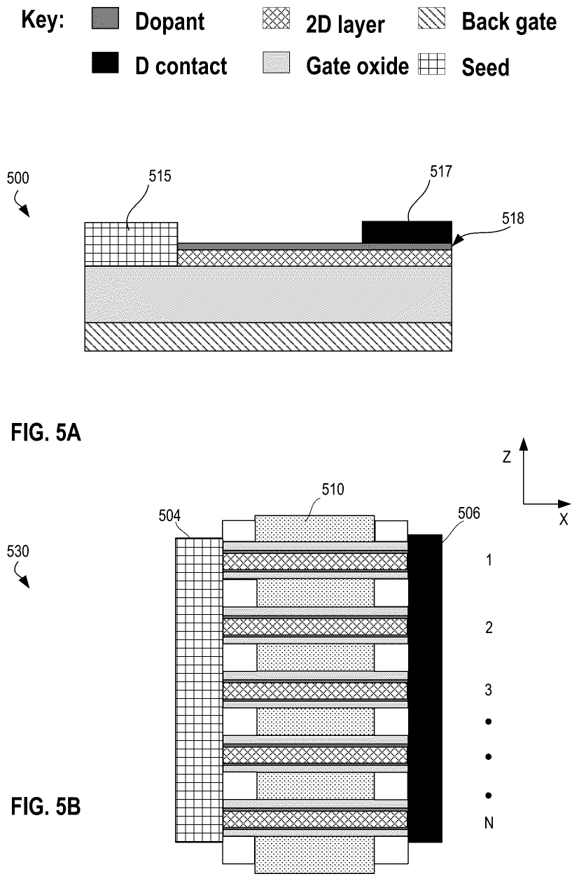

In fabrication, the dopant layer 416 of oxide material can be combined with either a gate oxide layer or a seed oxide layer from which the 2D material is grown. FIG. 5A illustrates using a seed layer 515 in a planar transistor fabrication and FIG. 5B illustrates using a seed layer 504 in a stacked nanoribbon transistor fabrication. Implementing the concepts developed in embodiments described above, the dopant layer 518 can be located on/along the channel region, or just below the spacer in conjunction with the oxide seed layer from which the 2D material is grown. The seed 504 could also act as a source or additional doping to the 2D material. In embodiment 500, a source contact 515 comprises a seed. In various embodiments, the seed may be WOx, MoOx, InOx, or another relevant oxide for the 2D material of the channel.

Prior to selecting one of the options at 604, 606, 608, or 610, respective source/drain locations are identified for a plurality of 2D transistor devices, in the 2D channel material. In various embodiments, a layer of resist or mask material is overlaid on the layer of 2D material (at and then patterned (i.e., removed) to expose the regions of the 2D material that are intended/identified to be the source and drain (also referred to as a first S/D region 103/107/304/404/504 and a second S/D region 105/109/306/406/506).

In embodiments of FeFET devices, a ferromagnetic material may surround the channel, in the interface between the 2D channel material and the gate oxide.

At 612, embodiments with the above-described transistor architecture may be further fabricated or assembled into another device or package assembly. Accordingly, at 612, gate controls and material may be added, and singulation and assembly may be performed. Embodiments can be found in planar FETs, nanoribbon FETs, FeFETs, etc.; and further, these transistors can be found in a variety of package assemblies and devices, such as, central processing units (CPUs), graphics processing units (GPUs), artificial intelligence (AI) processing units, logic, memory components, etc.

Thus, methods for doping 2d transistor devices and resulting architectures have been described. To summarize, unique features of this disclosure include distinct stoichiometry compositions as well as notably improved threshold voltage performance and/or contact resistance. As mentioned above, in addition to the distinct compositional analysis from doping the 2D material with the disclosed oxide(s), transistors that practice the architectures/compositions disclosed herein can be identified by their notable transistor performance improvements. The following description and associated figures provide more detail for components referenced hereinabove.

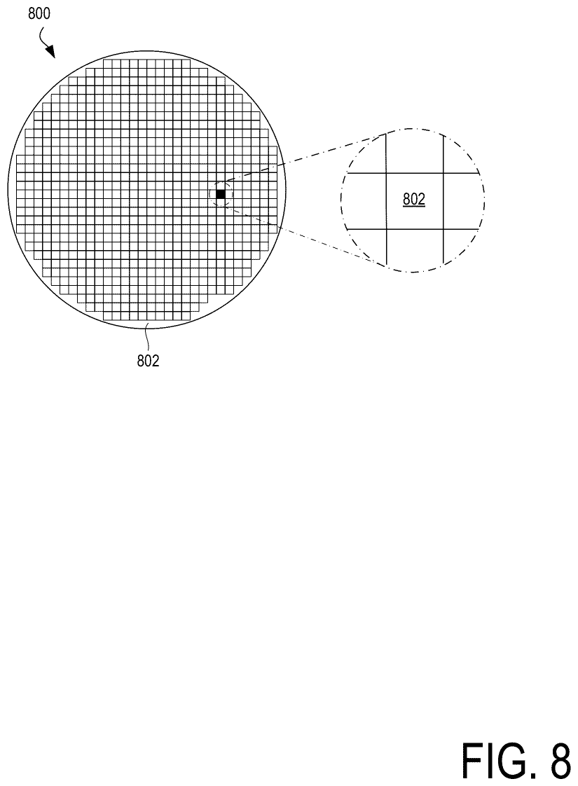

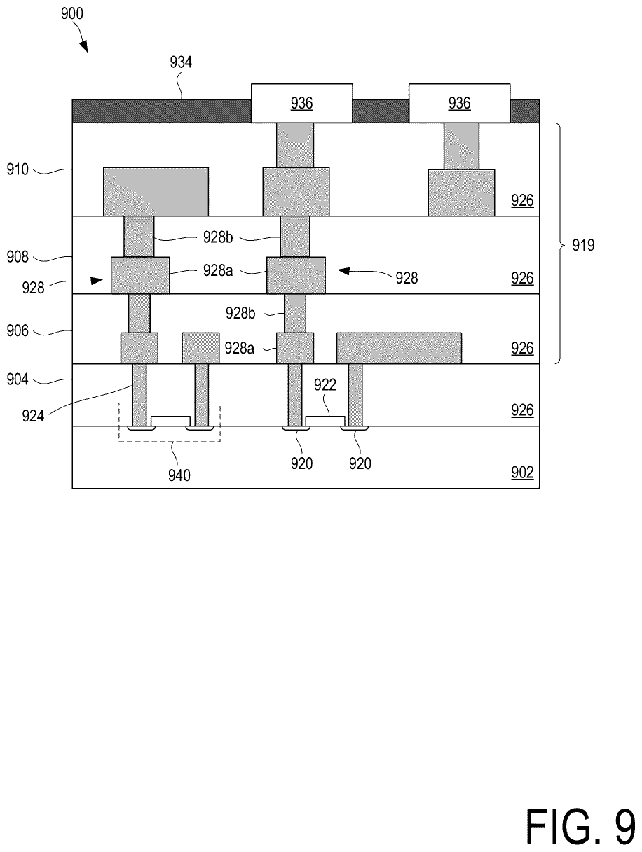

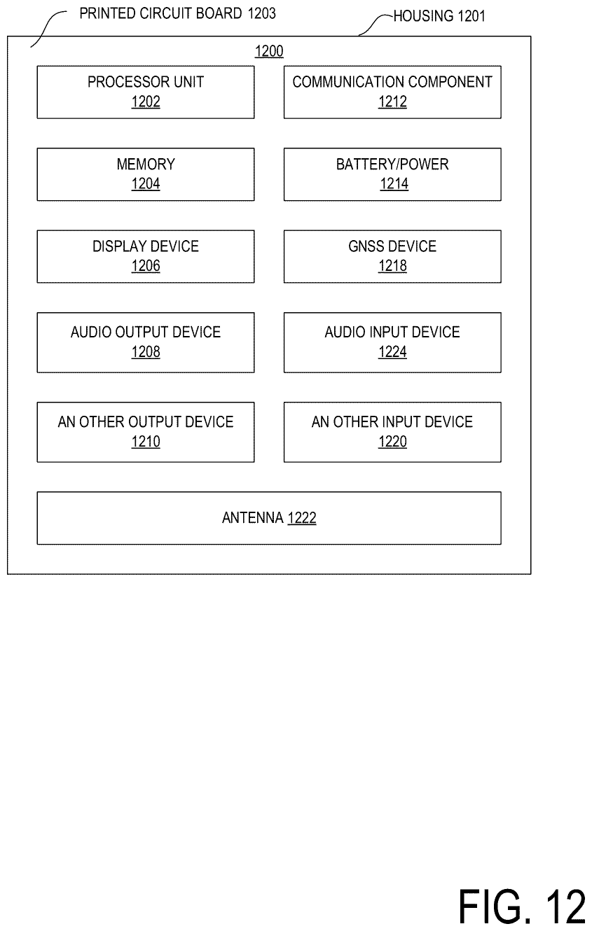

FIG. 8 is a top view of a wafer 800 and dies 802 that may be included in any of the embodiments disclosed herein. The wafer 800 may be composed of semiconductor material and may include one or more dies 802 formed on a surface of the wafer 800. After the fabrication of the integrated circuit components on the wafer 800 is complete, the wafer 800 may undergo a singulation process in which the dies 802 are separated from one another to provide discrete “chips” or destined for a packaged integrated circuit component. The individual dies 802, comprising an integrated circuit component, may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. In some embodiments, a die 802 may be attached to a wafer 800 that includes other die, and the wafer 800 is subsequently singulated, this manufacturing procedure is referred to as a die-to-wafer assembly technique.

FIG. 9 is a cross-sectional side view of an integrated circuit 900 that may be included in any of the embodiments disclosed herein. One or more of the integrated circuits 900 may be included in one or more dies 802 (FIG. 8). The integrated circuit 900 may be formed on a die substrate 902 (e.g., the wafer 800 of FIG. 8) and may be included in a die (e.g., the die 802 of FIG. 8).

The die substrate 902 may be a semiconductor substrate composed of semiconductor material systems including, for example, n-type transistors or material or p-type transistors or material systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit 900 may be used. The die substrate 902 may be part of a singulated die (e.g., the dies 802 of FIG. 8) or a wafer (e.g., the wafer 800 of FIG. 8).

The integrated circuit 900 may include one or more device layers 904 disposed on the die substrate 902. The device layer 904 may include features of one or more transistors 940 (e.g., complementary metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920.

The gate 922 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may comprise a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be conducted to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuits having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928a/b of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit 900 with another component (e.g., a printed circuit board). The integrated circuit 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit 900 is a double-sided die, the integrated circuit 900 may include another metallization stack (not shown) on the opposite side of the device layer(s) 904. This metallization stack may include multiple interconnect layers as discussed above with reference to the interconnect layers 906-910, to provide electrically conductive paths (e.g., including conductive lines and vias) between the device layer(s) 904 and additional conductive contacts (not shown) on the opposite side of the integrated circuit 900 from the conductive contacts 936.

In other embodiments in which the integrated circuit 900 is a double-sided die, the integrated circuit 900 may include one or more through-silicon vias (TSVs) through the die substrate 902; these TSVs may make contact with the device layer(s) 904, and may provide electrically conductive paths between the device layer(s) 904 and additional conductive contacts (not shown) on the opposite side of the integrated circuit 900 from the conductive contacts 936. In some embodiments, TSVs extending through the substrate can be used for routing power and ground signals from conductive contacts on the opposite side of the integrated circuit 900 from the conductive contacts 936 to the transistors 940 and any other components integrated into the die of the integrated circuit 900, and the metallization stack 919 can be used to route I/O signals from the conductive contacts 936 to transistors 940 and any other components integrated into the die of the integrated circuit 900.

Multiple integrated circuits 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

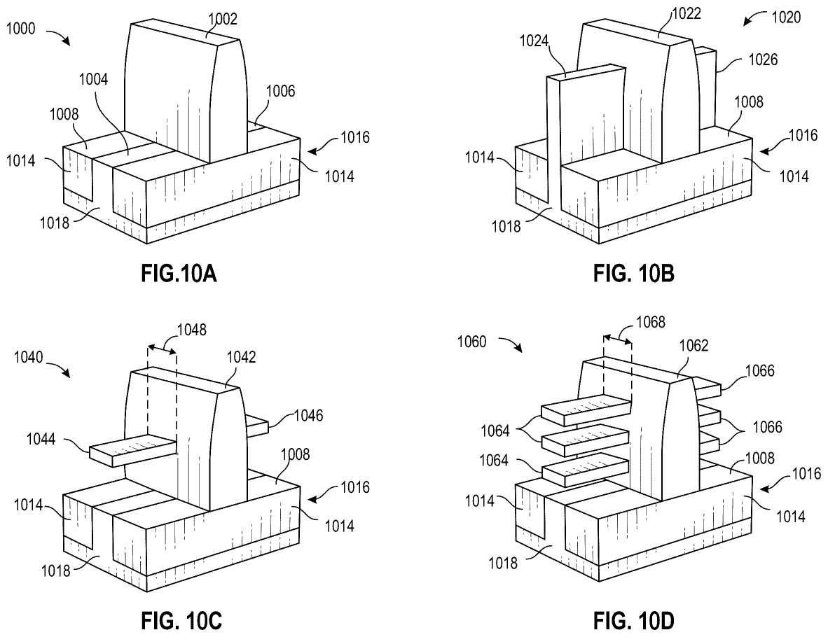

FIGS. 10A-10D are simplified perspective views of example planar, FinFET, gate-all-around, and stacked gate-all-around transistors. The transistors illustrated in FIGS. 10A-10D are formed on a substrate 1016 having a surface 1008. Isolation regions 1014 separate the source and drain regions of the transistors from other transistors and from a bulk region 1018 of the substrate 1016.

FIG. 10A is a perspective view of an example planar transistor 1000 comprising a gate 1002 that controls current flow between a source region 1004 and a drain region 1006. The transistor 1000 is planar in that the source region 1004 and the drain region 1006 are planar with respect to the substrate surface 1008.

FIG. 10B is a perspective view of an example FinFET transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1008. As the gate 1022 encompasses three sides of the semiconductor fin that extends from the source region 1024 to the drain region 1026, the transistor 1020 can be considered a tri-gate transistor. FIG. 10B illustrates one S/D fin extending through the gate 1022, but multiple S/D fins can extend through the gate of a FinFET transistor.

FIG. 10C is a perspective view of a gate-all-around (GAA) transistor 1040 comprising a gate 1042 that controls current flow between a source region 1044 and a drain region 1046. The transistor 1040 is non-planar in that the source region 1044 and the drain region 1046 are elevated from the substrate surface 1008.

FIG. 10D is a perspective view of a GAA transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the semiconductor portions that extend from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the semiconductor portions extending through the gate.

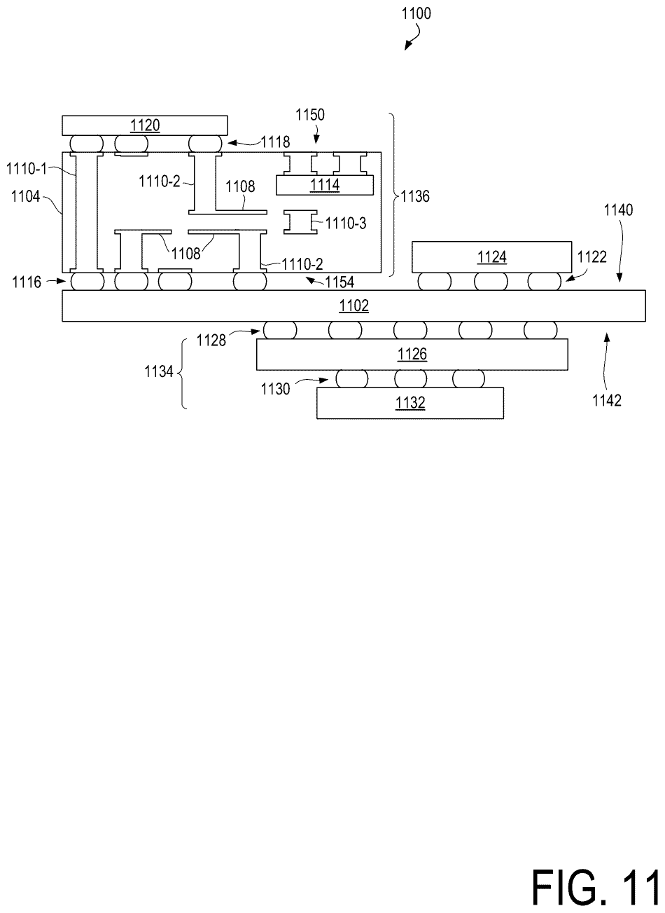

FIG. 11 is a cross-sectional side view of a microelectronic assembly 1100 that may include any of the embodiments disclosed herein. The microelectronic assembly 1100 includes multiple integrated circuit components disposed on a circuit board 1102 (which may be a motherboard, system board, mainboard, etc.). The microelectronic assembly 1100 may include components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The microelectronic assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit component that includes one or more integrated circuit dies (e.g., the die 802 of FIG. 8, the integrated circuit 900 of FIG. 9) and/or one or more other suitable components.

The unpackaged integrated circuit component 1120 comprises solder bumps attached to contacts on the die. The solder bumps allow the die to be directly attached to the interposer 1104. In embodiments where the integrated circuit component 1120 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through-silicon vias (TSV) extending through the silicon interposer can connect connections on the first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the disclosed embodiments, semiconductor assemblies, package assemblies, microelectronic assemblies 1100, integrated circuit components 1120, integrated circuits 900, integrated circuit dies 802, or structures disclosed herein, attached on a printed circuit board 1201. A number of components are illustrated in FIG. 12 as included in the electrical device 1200, but any one or more of these components may be omitted or duplicated, as suitable for the application. In some embodiments, some or all the components included in the electrical device 1200 may be attached to one or more motherboards, mainboards, printed circuit boards, or system boards. In some embodiments, one or more of these components are fabricated onto a single system-on-a-chip (SoC) die. In various embodiments, the electrical device 1200 is enclosed by, or integrated with, a housing 1203.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processor units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include power supply such as a battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a field effect transistor comprising: a first layer comprising oxide; a channel material comprising transition metal atoms and chalcogen atoms overlaid on the first layer; and a second layer comprising an oxide material overlaid on a region of the channel material, and wherein the oxide material comprises germanium.

Example 2 is an apparatus, comprising: a field effect transistor comprising: a first layer comprising oxide; a channel material comprising transition metal atoms and chalcogen atoms overlaid on the first layer; and a second layer comprising an oxide material overlaid on a region of the channel material, and wherein the oxide material comprises at least one of tungsten, molybdenum, magnesium, aluminum, germanium, vanadium, indium, hafnium, or lanthanum.

Example 3 includes the subject matter of Example 1 or Example 2, wherein the channel material is a two-dimensional (2D) material.

Example 4 includes the subject matter of any one of Examples 1-3, wherein the channel material is between 0.7 and 2.8 nanometers thick.

Example 5 includes the subject matter of any one of Examples 1-4, wherein the transition metal atoms comprise molybdenum, indium, or tungsten.

Example 6 includes the subject matter of any one of Examples 1-5, wherein the channel material comprises WSe2, MoS2, MoTe2, In Se2, In2Se3, or WS2.

Example 7 includes the subject matter of any one of Examples 1-6, further comprising a first source/drain metal contact and a second source/drain metal contact, and wherein the region is located exclusively between the first source/drain metal contact and the second source/drain metal contact, on a surface of the channel material.

Example 8 includes the subject matter of Example 7, wherein a threshold voltage measured for the field effect transistor is greater than zero +/−2 volts.

Example 9 includes the subject matter of any one of Examples 1-6, further comprising a source/drain metal contact and wherein the region is located between the source/drain metal contact and a surface of the channel material.

Example 10 includes the subject matter of Example 8, wherein a contact resistance measured between the source/drain metal contact and the region is less than 100 ohm/micrometer.

Example 11 includes the subject matter of any one of Examples 1-10, further comprising a metal layer under the oxide, the metal layer to be a back-gate.

Example 12 includes the subject matter of any one of Examples 1-11, further comprising an integrated circuit die comprising the field effect transistor.

Example 13 is an apparatus comprising: a complementary metal oxide semiconductor (CMOS) circuit comprising: a P-type field effect transistor (FET) comprising a channel material comprising transition metal atoms and chalcogen atoms; and an N-type FET comprising the channel material; and a layer comprising an oxide material overlaid on a region of the channel material, and wherein the oxide material comprises at least one of tungsten, molybdenum, magnesium, aluminum, germanium, vanadium, indium, hafnium, or lanthanum.

Example 14 includes the subject matter of Example 13, wherein the P-type FET and N-type FET comprise respective drain contacts coupled together, and respective gate contacts coupled together.

Example 15 includes the subject matter of Example 13, wherein the P-type FET comprises a first drain contact and first source contact, and the N-type FET comprises a second drain contact and a second source contact, and wherein the region is located exclusively between the first drain contact and the first source contact, or exclusively between the second drain contact and the second source contact.

Example 16 includes the subject matter of Example 13, wherein the P-type FET comprises a first source/drain contact, and the N-type FET comprises a second source/drain contact, and wherein the region is located exclusively between the first source/drain contact and the channel material or exclusively between the second source/drain contact and the channel material.

Example 17 includes the subject matter of Example 13, wherein the CMOS circuit is operable to function as either a memory element or a logic element dependent on one or more bias voltages applied to the circuit.

Example 18 is a method comprising: forming an oxide layer over a substrate; forming a two-dimensional (2D) channel material on the substrate, the channel material comprising transition metal atoms and chalcogen atoms; identifying a first source/drain location and a second source/drain location in the 2D channel material; determining a region on a surface of the 2D channel material to apply an oxide dopant layer; and overlaying the oxide dopant layer on the region, wherein the oxide dopant layer comprises at least one of tungsten, molybdenum, magnesium, aluminum, germanium, vanadium, indium, hafnium, or lanthanum.

Example 19 includes the subject matter of Example 18, further comprising determining that the region is between the first source/drain location and the second source/drain location.

Example 20 includes the subject matter of Example 18, further comprising determining that the region is between the first source/drain location and the 2D channel material.

Example 21 includes the subject matter of Example 18, further comprising forming the 2D material with WSe₂ and the oxide dopant layer comprises GeOx.

What is claimed is:

1. An apparatus, comprising:
a field effect transistor comprising:
a first layer comprising oxide;
a channel material comprising transition metal atoms and chalcogen atoms overlaid on the first layer; and
a second layer comprising an oxide material overlaid on a region of the channel material, and wherein the oxide material comprises at least one of tungsten, molybdenum, magnesium, aluminum, germanium, vanadium, indium, hafnium, or lanthanum.

2. The apparatus of claim 1, wherein the channel material is a two-dimensional (2D) material.

3. The apparatus of claim 1, wherein the channel material is between 0.7 and 2.8 nanometers thick.

4. The apparatus of claim 1, wherein the transition metal atoms comprise molybdenum, indium, or tungsten.

5. The apparatus of claim 1, wherein the channel material comprises sulfur, selenium, or tellurium.

6. The apparatus of claim 1, further comprising a first source/drain metal contact and a second source/drain metal contact, and wherein the region is located exclusively between the first source/drain metal contact and the second source/drain metal contact, on a surface of the channel material.

7. The apparatus of claim 6, wherein a threshold voltage measured for the field effect transistor is greater than zero +/−2 volts.

8. The apparatus of claim 1, further comprising a source/drain metal contact and wherein the region is located between the source/drain metal contact and a surface of the channel material.

9. The apparatus of claim 8, wherein a contact resistance measured between the source/drain metal contact and the region is less than 100 ohm/micrometer.

10. The apparatus of claim 1, further comprising a metal layer under the oxide, the metal layer to be a back-gate.

11. The apparatus of claim 1, further comprising an integrated circuit die comprising the field effect transistor.

12. An apparatus comprising:
a complementary metal oxide semiconductor (CMOS) circuit comprising:
a P-type field effect transistor (FET) comprising a channel material comprising transition metal atoms and chalcogen atoms; and
an N-type FET comprising the channel material; and
a layer comprising an oxide material overlaid on a region of the channel material, and wherein the oxide material comprises at least one of tungsten, molybdenum, magnesium, aluminum, germanium, vanadium, indium, hafnium, or lanthanum.

13. The apparatus of claim 12, wherein the P-type FET and N-type FET comprise respective drain contacts coupled together, and respective gate contacts coupled together.

14. The apparatus of claim 12, wherein the P-type FET comprises a first drain contact and first source contact, and the N-type FET comprises a second drain contact and a second source contact, and wherein the region is located exclusively between the first drain contact and the first source contact, or exclusively between the second drain contact and the second source contact.

15. The apparatus of claim 12, wherein the P-type FET comprises a first source/drain contact, and the N-type FET comprises a second source/drain contact, and wherein the region is located exclusively between the first source/drain contact and the channel material or exclusively between the second source/drain contact and the channel material.

16. The apparatus of claim 12, wherein the CMOS circuit is operable to function as either a memory element or a logic element dependent on one or more gate voltages applied to the circuit.

17. A method comprising:
forming an oxide layer over a substrate;
forming a two-dimensional (2D) channel material on the substrate, the 2D channel material comprising transition metal atoms and chalcogen atoms;
identifying a first source/drain location and a second source/drain location in the 2D channel material;
determining a region on a surface of the 2D channel material to apply an oxide dopant layer; and
overlaying the oxide dopant layer on the region, wherein the oxide dopant layer comprises at least one of tungsten, molybdenum, magnesium, aluminum, germanium, vanadium, indium, hafnium, or lanthanum.

18. The method of claim 17, further comprising determining that the region is between the first source/drain location and the second source/drain location.

19. The method of claim 17, further comprising determining that the region is between the first source/drain location and the 2D channel material.

20. The method of claim 17, further comprising forming the 2D channel material with WSe2 and the oxide dopant layer comprises GeOx.
